(19) United States
(12) Patent Application Publication
(10) Pub. No.: US 2021/0057396 A1
(43) Pub. Date: Feb. 25, 2021

(54) LED DISPLAY SCREEN AND MANUFACTURING METHOD THEREFOR

(71) Applicant: XIAMEN SAN'AN OPTOELECTRONICS CO., LTD., Xiamen (CN)

(72) Inventors: Ji-Pu WU, Xiamen (CN); Tsung-Ming LIN, Xiamen (CN); Yu-Tsai TENG, Xiamen (CN); Ho-Chia TSENG, Xiamen (CN)

(21) Appl. No.: 17/090,907

(22) Filed: Nov. 6, 2020

Related U.S. Application Data
(63) Continuation of application No. PCT/CN2019/074639, filed on Feb. 2, 2019.

(51) Int. Cl. H01L 25/075; H01L 21/67; H01L 33/62; B65G 47/90

(52) U.S. Cl. CPC H01L 25/0753; H01L 21/67144; H01L 2933/0066; B65G 47/90; H01L 33/62

(57) ABSTRACT

The present disclosure provides a manufacturing method for an LED display screen. The method includes preparing a batch of LED chips of the same or different specification; picking up the LED chips illogically according to a random sampling method, and arranging the picked led chips in sequence; and packaging and assembling the LED chips arranged in sequence to form the LED display screen. The LED display screen includes an area which includes a plurality of LED chips, and at least two adjacent LED chips of the plurality of LED chips are of different specifications, the specification of the LED chip comprising a specification of at least one of color and brightness.

### CROSS REFERENCE TO RELATED APPLICATIONS

This application is a continuation application for International Application PCT/CN2019/074639, filed on Feb. 2, 2019, the entirety of which is incorporated by reference herein for all purposes.

### TECHNICAL FIELD

The present disclosure relates to a technical field of LED chip sorting machine and LED display screen, and more particularly to a flip-chip LED display screen and a manufacturing method therefor.

### BACKGROUND

In a field of an LED display screen, users hope to obtain a clear display effect, and gradually pay more attention to a consistency of an overall screen effect. In a stage of point testing and sorting when preparing a chip, according to a sorting/arranging logic for the chip in the related art, the chips with a same bin specification will be arranged in sequence. When a packaging manufacturer packages the chips mentioned above in sequence and then assembles a screen subsequently, a problem of chromaticity difference in the display effect of a whole screen has gradually appeared, and a brightness difference and a color difference between screens will appear. Therefore, how to eliminate the brightness difference and the color difference among the screens has become a key issue in an entire field of LED display screen manufacturing.

In order to solve brightness and color problems among the screens mentioned above, in a field of surface mounted device (SMD) packaging, a phenomenon of color difference is eliminated mainly by a three-time mixing for the chips: (1) mixing blue films of different batches; (2) mixing lamp beads after SMD packaging; (3) mixing an SMD braid. In SMD packaging, a problem of color difference among modules is eliminated through the three-time mixing. However, since three stages of process are required, and at the same time, in a first stage of mixing the blue films of different batches, a part of a previous batch of blue films need to be retained in each time of blue film mixing, problems such as low production efficiency, uneven chip mixing, and incomplete mixing exist. In a field of chip-on-board (COB) packaging, in order to solve a chromaticity difference problem in the modules, a current mainstream solution of various packaging manufacturers is to perform chromaticity correction on the whole screen. However, due to the cost of correction equipment, the imperfection of correction technology, and differences in packaged products, the chromaticity difference problem in the modules cannot be fundamentally solved.

### SUMMARY

In view of the defects in the related art mentioned above, an objective of the present disclosure is to provide a LED display screen and a manufacturing method therefor for resolving differences in brightness and color among screens more conveniently and reliably.

In order to achieve the above objective and other related objectives, a first aspect of the present disclosure provides a manufacturing method for an LED display screen, including: preparing a batch of LED chips of the same or different specification; picking up the LED chips illogically according to a random sampling method, and arranging the picked LED chips in sequence; packaging and assembling the LED chips arranged in sequence to form the LED display screen. The LED display screen comprises an area comprising a plurality of LED chips, and at least two adjacent LED chips of the plurality of LED chips are of different specifications, the specification of the LED chip comprising a specification of at least one of color and brightness.

A second aspect of the present disclosure provides an LED display screen, including: a display unit including a circuit substrate and LED chips soldered on the circuit substrate. The LED chips include LED chips from a same wafer and/or LED chips from different wafers; the LED chips are picked up illogically and arranged and then soldered on the circuit substrate; at least two adjacent LED chips are of different specifications; and the specification of the LED chip includes at least one of color and brightness of the LED chip.

### BRIEF DESCRIPTION OF THE DRAWINGS

FIG. 1 is a schematic diagram showing an arrangement of LED chips after sorting/arraying in the related art;

FIG. 2 is a schematic flowchart showing a manufacturing method for an LED package device provided in a first embodiment;

FIG. 3 is a schematic diagram showing a structure of LED chips classified in different Bins according to the method shown in FIG. 2;

FIG. 4 is a schematic diagram showing a structure of the sorted LED chips after being performed a random arrangement according to the method shown in FIG. 2;

FIG. 5 is a schematic diagram showing a picking up process of a random arrangement for LED chips;

FIG. 6 is a schematic diagram showing an arrangement of the picked LED chips; and

FIGS. 7a-8b are schematic diagrams showing a display effect according to a related art sorting method and a display effect of a flip-chip LED display screen formed by packaging the randomly arranged LED chips according to the method shown in FIG. 2; FIG. 7a is a schematic diagram showing a display effect of a flip-chip LED display screen with a brightness step of 0.5 mW according to the related art; FIG. 7b is a schematic diagram showing a display effect of a flip-chip LED display screen with a brightness step of 0.5 mW formed by the method shown in FIG. 2; FIG. 8a shows a schematic diagram showing a display effect of a flip-chip LED display screen with a wavelength step of 0.5 nm according to the related art; FIG. 8b is a schematic diagram showing a display effect of a flip-chip LED display screen with a wavelength step of 0.5 nm formed by the method shown in FIG. 2.

Description of Reference Numerals: 10, Display Module; 101, LED Chip; 30, Display Module; 301, LED Chip.

### DETAILED DESCRIPTION OF THE EMBODIMENTS

An embodiment of the present disclosure will be described below through an exemplary embodiment. Those skilled in the art can easily understand other advantage and effect of the present disclosure according to content disclosed in the Description. The present disclosure can also be implemented or applied through other different exemplary embodiment. Various modifications or changes can also be made to all details in the Description based on different points of view and applications without departing from a spirit of the present disclosure.

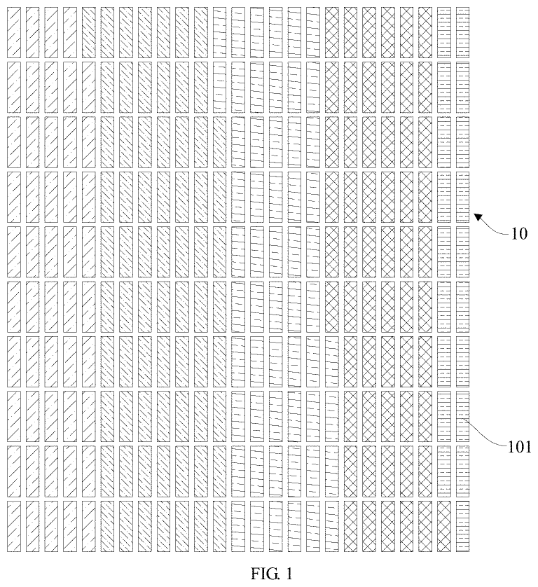

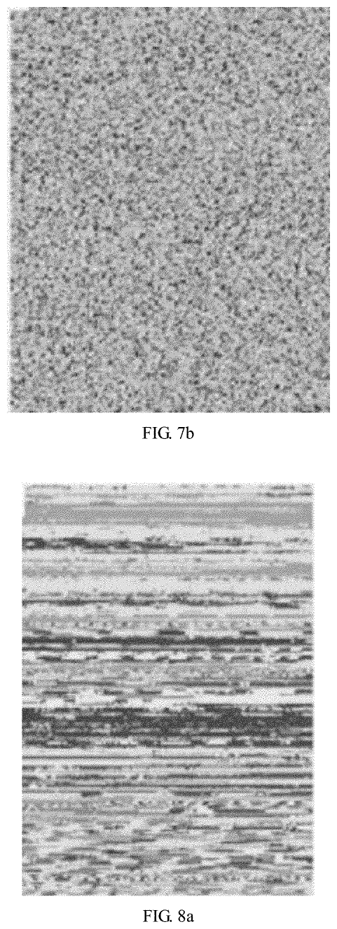

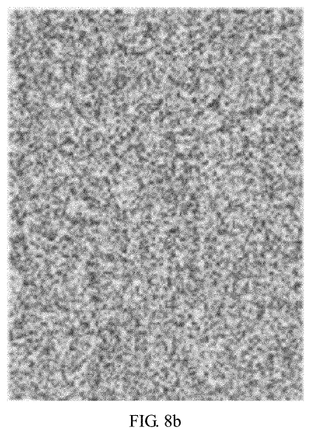

In an LED display screen manufacturing process, sorting LED chips is a very important step. A sorting/arraying technology in the related art usually arranges the LED chips logically, and the LED chips 101 of the same bin specification are arranged sequentially to form a display module 10, as shown in FIG. 1. According to the above sorting/arraying, after the display module 10 is assembled into an LED screen after subsequent packaging, a brightness difference and a color difference will appear between screens, and a striped or blocky color difference/brightness difference will appear, as shown in FIGS. 7a and 8a.

### Embodiment 1

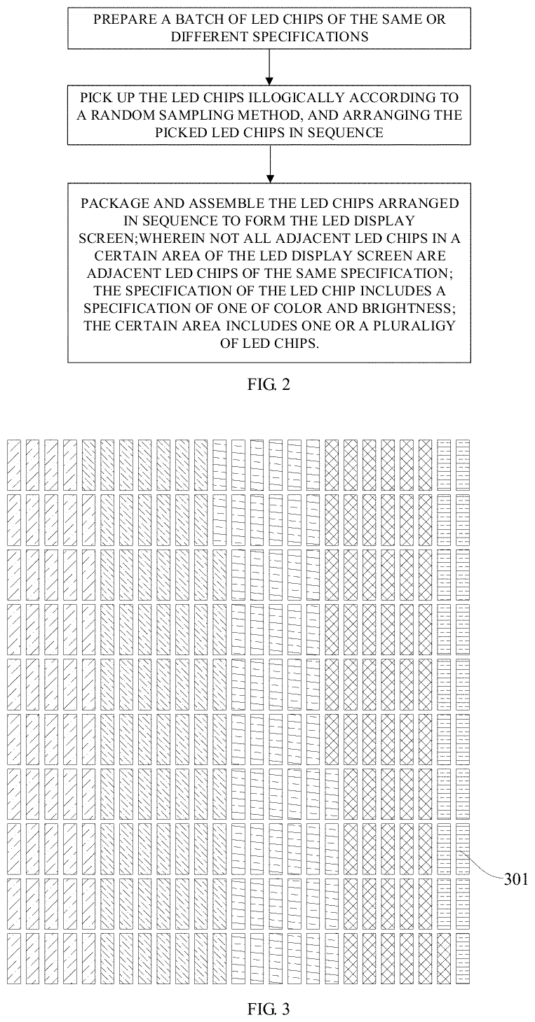

In order to solve a problem of brightness difference and color difference among screens caused by LED sorting in the related art, a manufacturing method for a flip-chip LED display screen is provided in the present embodiment, as shown in FIGS. 2-6, including the following steps.

A batch of LED chips of the same or different specifications is prepared.

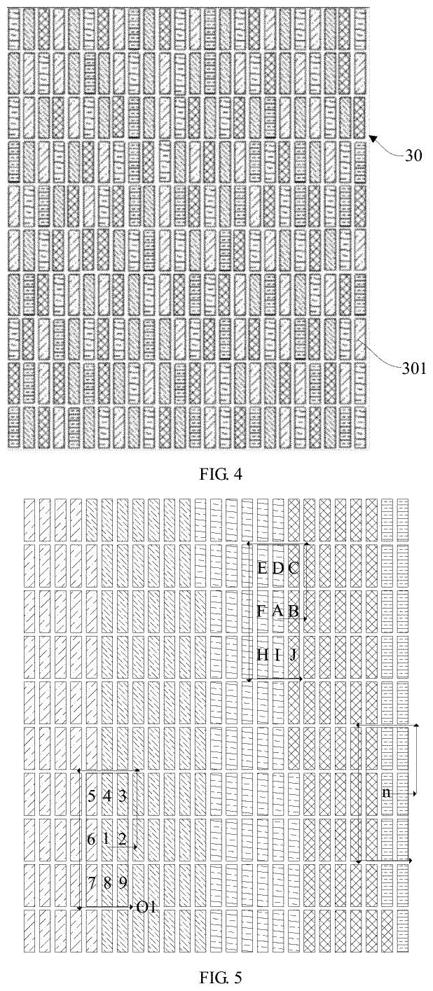

The above-mentioned LED chips of the same or different specifications can be from a same wafer or from different wafers. In an embodiment, as shown in FIG. 3, it shows that LED chips 301 of the same specification from different wafers are classified into different bins. In an embodiment, the LED chips can also be classified into a same bin but with different brightness or wavelengths. In the present embodiment, the specifications of the LED chips 301 include the specification of at least one of color and brightness.

The LED chips are picked up illogically according to a random sampling method, and the picked LED chips are arranged on a substrate.

As shown in FIG. 4, a display module 30 presented after the LED chips being picked up illogically and arranged is shown. It can be seen from FIG. 4 that the LED chips 301 in the display module 30 formed after the picking up and the arranging mentioned above are distributed in the display module 30 in a scattered and even manner.

The LED chips arranged on the substrate are packaged and transferred to a circuit substrate, and are assembled to form the LED display screen. The packaged LED chips can be transferred one by one sequentially to the circuit substrate or a plurality of the packaged LED chips can be transferred in a batch to the circuit substrate.

After the display module 30 as shown in FIG. 4 forms an LED display, not all the adjacent LED chips in a certain area of the LED display screen are adjacent LED chips of the same specification, and the certain area includes one LED chip or more. The certain area may be, for example, consisted of 3×4 LED chips, 6×8 LED chips, 2×5 LED chips, or the like. There will be no striped or blocky color difference and brightness difference phenomena between screens. As shown in FIGS. 7b and 8b, no matter the bins are classified according to a same brightness and different wavelengths (colors) or are classified according to a same wavelength and different brightness, after the picking up illogically and the arranging mentioned above, the LED chips 301 are distributed in each display module 30 in a scattered and even manner. Therefore, after the display module 30 is assembled into a display screen, there will be no striped or blocky color difference/brightness difference between screens.

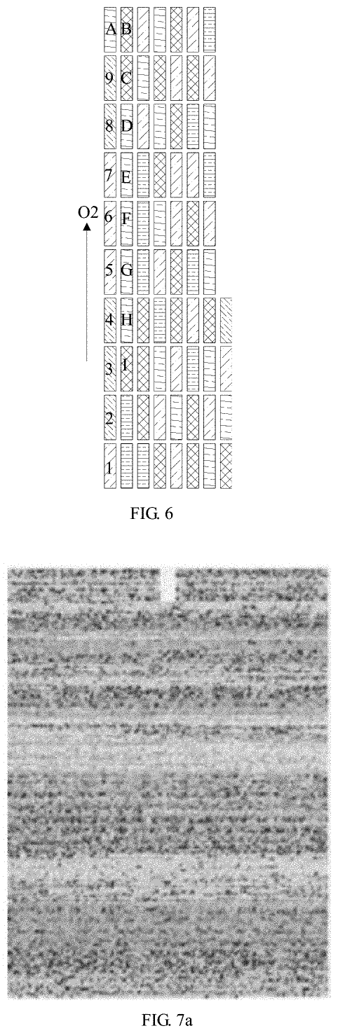

In an embodiment, as shown in FIGS. 5 and 6, a process of picking up and arranging the LED chips of the same specification from different wafers is shown.

As shown in FIG. 5, firstly, the LED chips of the same specification from different wafers are placed on one or more carrier films sequentially. The carrier film can be any adhesive carrier film such as blue film, white film, PVC film, or the like. Then, the LED chips mentioned above are picked up illogically according to the random sampling method. In an embodiment, the random sampling method includes a random number table method, and a random number table in the random number table method includes one of a Fisher-Yates random number table, a Tippet random number table, and a Kendell-Smith random number table. In the present embodiment, the random number table method is used to pick up the above-mentioned LED chips illogically. Firstly, the first picking point is randomly selected, and the LED chip 1 at the first picking point is picked up, or the LED chip 1 at the first picking point is picked up and at the same time the LED chips around the first picking point are sequentially picked up along a predetermined picking direction O1. For example, a first number of LED chips ranging from one to eight around the first picking point can be picked up. In the present embodiment, eight LED chips 2-9 around the first picking point are picked up. The picking direction O1 may be a counterclockwise direction or a clockwise direction. In an embodiment, as shown in FIG. 5, the picking direction O1 is a counterclockwise direction.

The LED chip 1 at the first picking point and the LED chips 2-9 around it are arranged on the substrate in sequence in a predetermined arrangement manner. The predetermined arrangement manner can be determined according to a final product requirement of the LED display screen. For example, as shown in FIG. 6, the predetermined arrangement manner includes a vertical turn-back arrangement manner O2, and of course, it may also be a horizontal turn-back arrangement manner.

After picking up and arranging the LED chips at the first picking point, randomly jump to a second picking point and the LED chip A at the second picking point is picked up, or the LED chip A at the second picking point is picked up and at the same time a second number of the LED chips around the second picking point are sequentially picked up along the predetermined picking direction O1. For example, eight LED chips B-I around the second picking point are also picked up. Then, the LED chip A at the second picking point and the LED chips B-I around it are arranged on the substrate in sequence in a predetermined arrangement manner.

. . .

Jump to an n-th picking point randomly, and the LED chip at the n-th picking point and an n-th number of LED chips around the n-th picking point are picked up along the predetermined picking direction.

The LED chip and the n-th number of LED chips picked at the n-th picking point are arranged on the substrate in sequence according to the predetermined arrangement manner.

The above-mentioned steps of picking up and arranging randomly are repeated until all the LED chips are picked up and arranged, and a required arrangement pattern is formed. The arrangement pattern can also be determined according to the final product requirement of the LED display screen.

As shown in FIGS. 5 and 6, the first picking point, the second picking point, . . . and the n-th picking point include illogical points that are randomly selected by the random sampling method; the first number of LED chips, the second number of LED chips, . . . and the n-th number of LED chips include 0 to 8 LED chips. Further, n is an integer greater than 2.

Then, the LED chips placed on the substrate are packaged and transferred onto the circuit substrate to form the display module shown in FIG. 4, and the display module is assembled to form the LED display screen.

As shown in FIG. 4, the LED chips in each display module are distributed in a scattered and even manner. Thus, after the LED display screen is formed, the striped or blocky color difference/brightness difference will not appear between screens.

In order to obtain a more scattered and even distribution of LED chips, and as far as possible to completely eliminate the striped or blocky color difference/brightness difference that may appear between screens, the steps of picking up illogically and arranging sequentially can be repeated many times, until reaching a desired display effect.

### Embodiment 2

The present embodiment provides a manufacturing method for the flip-chip LED display screen. Same parts as those in the first embodiment will not be repeated here, and a difference is as follows.

In the present embodiment, the LED chips can be picked up directly from a wafer from which the LED chips are cut out illogically according to the random sampling method; then the picked LED chips are arranged on the carrier film, which can also be any adhesive carrier film such as a blue film, a white film and a PVC film; then the LED chips on the carrier film are transferred onto the circuit substrate in a batch; and the LED chips transferred onto the circuit substrate are packaged and assembled to form the LED display screen.

According to the method shown in the above embodiment of the present disclosure, the LED chips of the same or different specifications from the same wafer can be picked up illogically directly and then be arranged. Therefore, the method can directly pick up the LED chips without classifying the bin of the LED chips, and realize a scattered and even distribution of the LED chips. In addition, according to this method, the LED chips of different bins of the same specification from different wafers can also be picked up illogically and arranged. That is, the scattered and even distribution of the LED chips of different bins is realized. The above method enables the LED chips to be distributed in a scattered and even manner in a final LED screen, without causing striped or blocky color difference/brightness difference between screens.

In addition, the above method can realize the scattered and even distribution of the LED chips by performing the picking up illogically only once, and thus a realization process is simple, and a sorting cost is low.

In another embodiment, the LED chips mentioned above include a flip-chip Mini LED chip or a flip-chip Micro LED chip.

### Embodiment 3

An LED display screen is provided in the present embodiment. The LED display screen includes a display unit, and the display unit includes a circuit substrate and LED chips soldered on the circuit substrate.

The LED chips includes LED chips from a same wafer and/or LED chips from different wafers. The LED chips are arranged randomly and then soldered on the circuit substrate. Adjacent LED chips include no adjacent LED chips of the same specification. The specification of the LED chip includes at least one of color and brightness of the LED chip.

In an embodiment, the LED chip includes a flip-chip Mini LED chip or Micro LED chip.

In another embodiment, the LED display screen further includes a control system which is electrically connected with the display unit to control the display unit to display based on a different requirement.

According to the LED display screen of the present embodiment, the LED chips are arranged according to the method described in the first embodiment, so that the LED chips are distributed in a scattered and even manner in the LED display screen. Therefore, the LED display screen does not need to rely on a control of a system drive circuit to distribute current to make the brightness and color of the screen uniform, and there is no need to use Pulse Width Modulation (PWM) to adjust a duty cycle to achieve uniform brightness. The LED display screen has a function of independently turning on an R/G/B three-color light. A same drive current is used to turn on R/G/B, and the striped or blocky color difference/brightness difference will not appear in the LED display screen.

As mentioned above, the LED display screen and the manufacturing method therefor of the present disclosure provide the following beneficial effects.

According to the method of embodiments of the present disclosure, the chips in a single specification or a plurality of specifications are picked up illogically and arranged for one time or more. The chips picked up and arranged according to the above-mentioned method will not show differences in brightness and color after packaging and assembling the chips to form the screen subsequently. In addition, the method of the present disclosure can be realized by incorporating a random number table method into operation of an existing device, and a realization process is simple. There is no need to change or design the device or a manufacturing process, and an operating cost is low and the method is easy to realize.

According to this method, the LED chips of the same or different specifications from the same wafer can be picked up illogically directly and then be arranged. Therefore, the method can directly pick up the LED chips without classifying the bin of the LED chips, and realize a scattered and even distribution of the LED chips. In addition, according to this method, the LED chips of different bins of the same specification from different wafers can also be picked up illogically and arranged. That is, the scattered and even distribution of the LED chips of different bins is realized. The above method enables the LED chips to be distributed in a scattered and even manner in a final LED screen, without causing striped or blocky color difference/brightness difference between screens.

In addition, according to the method of embodiments of the present disclosure, the chips on a source side are randomly arranged, and the chips on the source side are randomly arranged on a product, which is easy to realize a mass production. In addition, since the chips within a package module or within the screen are arranged randomly, there is no striped or blocky color difference/brightness difference. When the module and the module or the screen and the screen are further assembled, a striped or blocky color difference/brightness difference phenomenon will not appear.

The above-mentioned embodiments are merely illustrative of a principle and an effect of the present disclosure instead of limiting the present disclosure. Those skilled in the art can make modifications or changes to the above-mentioned embodiments without going against the spirit and the range of the present disclosure. Therefore, all equivalent modifications or changes made by those skilled in the art without departing from the spirit and scope of the present disclosure will be covered by the appended claims.

What is claimed is:

1. A manufacturing method for an LED display screen, comprising:
preparing a batch of LED chips of the same or different specifications;
picking up the LED chips illogically according to a random sampling method, and arranging the picked led chips in sequence; and
packaging and assembling the LED chips arranged in sequence to form the LED display screen;
wherein the LED display screen comprises an area comprising a plurality of LED chips, and at least two adjacent LED chips of the plurality of LED chips are of different specifications, the specification of the LED chip comprising a specification of at least one of color and brightness.

2. The manufacturing method of claim 1, wherein the picking up the LED chips illogically according to the random sampling method, and arranging the picked LED chips in sequence comprises:
performing n times of a picking-arranging process, the picking-arranging process comprising selecting a picking point randomly and picking up the LED chip at the picking point and a number of LED chips around the picking point along a predetermined picking direction, and arranging the picked LED chip at the picking point and the number of LED chips in sequence according to a predetermined arrangement manner;
wherein n is an integer greater than 2;
wherein a first picking point is selected and a first number of LED chips around the first picking point are picked when performing the first time of the picking-arranging process; a second picking point is selected and a second number of LED chips around the second picking point are picked when performing the second time of the picking-arranging process; and a n-th picking point is selected and a n-th number of LED chips around the n-th picking point are picked when performing the n-th time of the picking-arranging process; and
wherein the LED chip at the n-th picking point and the n-th number of LED chips, the LED chip at the second picking point and the second number of LED chips, and the LED chip at the first picking point and the first number of LED chips are continuously arranged.

3. The manufacturing method of claim 2, wherein the predetermined picking direction comprises a counterclockwise direction or a clockwise direction, and the predetermined arrangement manner and the arrangement pattern are determined by a requirement of the LED display screen.

4. The manufacturing method of claim 2, wherein
the first picking point, the second picking point, and the n-th picking point comprise illogical points that are randomly selected by the random sampling method; and
the first number of LED chips, the second number of LED chips, and the n-th number of LED chips comprise 0 to 8 LED chips.

5. The manufacturing method of claim 1, wherein the batch of LED chips of the same or different specifications is from a wafer in a single specification or wafers in a plurality of specifications; and the LED chips comprises a flip-chip Mini LED or Micro LED chip.

6. The manufacturing method of claim 1, wherein the random sampling method comprises a random number table method, wherein a random number table comprises one of a Fisher-Yates random number table, a Tippet random number table, and a Kendell-Smith random number table.

7. The manufacturing method of claim 1, wherein the preparing the batch of LED chips of the same or different specifications comprises placing the LED chips of the same specification from different wafers sequentially on a plurality of carrier films.

8. The manufacturing method of claim 1, wherein the picking up the LED chips illogically according to the random sampling method, and arranging the picked LED chips in sequence comprises arranging the picked LED chips on a substrate in sequence.

9. The manufacturing method of claim 8, wherein the packaging and assembling the LED chips arranged in sequence to form the LED display screen comprises:
packaging the LED chips arranged on the substrate; and
transferring the packaged LED chips onto a circuit substrate and assembling the same to form the LED display screen;
wherein the transferring the packaged LED chips onto the circuit substrate comprises transferring the packaged LED chips one by one sequentially or transferring a plurality of the packaged LED chips in a batch.

10. The manufacturing method of claim 1, wherein the picking up the LED chips illogically according to a random sampling method, and arranging the picked LED chips in sequence further comprises:
picking up the LED chips directly from a wafer from which the LED chips are cut out illogically according to the random sampling method; and
arranging the picked LED chips on a carrier film.

11. The manufacturing method of claim 10, wherein the packaging and assembling the LED chips arranged in sequence to form the LED display screen comprises:
transferring the LED chips arranged on the carrier film onto a circuit substrate in a batch; and
packaging and assembling the LED chips transferred onto the circuit substrate to form the LED display screen.

12. The manufacturing method of claim 2, wherein the predetermined picking direction is formulated to pass at least two adjacent bins which having different specifications of brightness and/or color of the LED chips.

13. The manufacturing method of claim 12, wherein the predetermined picking direction is not same as the predetermined arrangement manner.

14. An LED display screen, comprising:
a display unit comprising a circuit substrate and LED chips soldered on the circuit substrate;
wherein the LED chips comprise LED chips from a same wafer and/or LED chips from different wafers; the LED chips are picked up illogically and arranged and then soldered on the circuit substrate; at least two adjacent LED chips are of different specifications; and the specification of the LED chip comprises the speciation of at least one of color and brightness of the LED chip.

15. The LED display screen of claim 14, wherein each two adjacent LED chips are of different specifications.

16. The LED display screen of claim 14, further comprising:
a control system electrically connected with the display unit to control the display unit to display based on a different requirement.

17. The LED display screen of claim 14, wherein the LED chips comprise a flip-chip Mini LED chip or Micro LED chip.
